(19) United States
(12) Patent Application Publication
(10) Pub. No.: US 2015/0263215 A1
(43) Pub. Date: Sep. 17, 2015

(54) WASHING ASSEMBLY AND METHOD FOR MONITORING THE PROCESS OF FABRICATING SOLAR CELLS

(71) Applicant: TSMC SOLAR LTD., Taichung City (TW)

(72) Inventor: Shih-Wei CHEN, Kaohsiung City (TW)

(73) Assignee: TSMC SOLAR LTD, Taichung City (TW)

(21) Appl. No.: 14/210,487

(22) Filed: Mar. 14, 2014

(51) Int. Cl. H01L 31/18; H01L 31/0749

(52) U.S. Cl. CPC H01L 31/186; H01L 31/0749

(57) ABSTRACT

A method for monitoring the process of fabricating solar cells includes delivering at least one solar cell substructure to a wash chamber having a wash solution therein, such that the solar cell substructure is at least partially immersed within the wash solution. A residual material is removed from the solar cell substructure using the wash solution. A pH value of the wash solution is detected automatically while the solar cell substructure is at least partially immersed within the wash solution, via a control apparatus. The method also includes determining whether the detected pH value is at a predefined threshold pH level or within a predefined pH range for the wash solution, via the control apparatus. The pH value of the wash solution is modified automatically if the detected pH value is different from the predefined threshold pH level or different from the predefined pH range.

### BACKGROUND

This disclosure relates to thin film photovoltaic solar cells. Photovoltaic cells or solar cells are components for direct generation of electrical current from sunlight. Due to the growing demand for clean sources of energy, the manufacture of solar cells has expanded dramatically in recent years and continues to expand. Solar cells include a substrate, a back contact layer on the substrate, an absorber layer on the back contact layer, a buffer layer on the absorber layer, and a front contact layer above the buffer layer. The layers can be applied onto the substrate during various deposition processes.

Semi-conductor materials are used in the manufacturing or fabrication of some solar cells by being used as the material to form at least a portion of the absorber layer. For example, chalcopyrite based semi-conductive materials, such as copper indium gallium sulfur-selenide (CIGSS) (also known as thin film solar cell materials), are used to complete the formation of the absorber layer after the deposition process. Some techniques that are used for the formation of CIGSS or thin film solar cell materials include a selenization process of metal precursors and a sulfurization process that is conducted after the selenization (the entire process is referred to as sulfurization after selenization (SAS)).

As the absorber layer is being formed onto the back contact layer and the substrate to form a solar cell substructure, some areas within the substructure can trap residual atoms or compounds. For example, the substrate can be formed of glass having polycrystalline materials that include relatively small pores or apertures. Residual atoms or compounds, such as sodium compounds Na₂Se and/or Na₂S, can become trapped within the pores or apertures. Such residual atoms or compounds on the substructure can have a negative impact on the overall performance of the solar cell. Therefore, in some embodiments, the solar cell substructure undergoes a washing or cleaning process prior to the buffer layer being formed onto the absorber layer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of an exemplary solar cell, in accordance with some embodiments.

FIG. 2 is a block diagram of an exemplary solar cell fabrication system used for fabricating the solar cell shown in FIG. 1, in accordance with some embodiments.

FIG. 3A is a block diagram of an exemplary washing assembly used with the solar cell fabrication system shown in FIG. 2 and taken from area 3, in accordance with some embodiments.

FIG. 3B is a diagram of a portion of the washing assembly shown in FIG. 3A and taken from area 4.

FIG. 4 is a flow diagram of an exemplary method for monitoring the process of fabricating the solar cell using the washing assembly shown in FIG. 3A, in accordance with some embodiments.

### DETAILED DESCRIPTION

The following disclosure provides many different embodiments, or examples, for implementing different features of the subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus or assembly may be otherwise oriented (rotated 90 degrees or at other orientations) and the spatially relative descriptors used herein may likewise be interpreted accordingly.

As used herein, the term “couple” is not limited to a direct mechanical, electrical, and/or communication connection between components, but may also include an indirect mechanical, electrical, and/or communication connection between multiple components.

As described above, when the absorber layer is being formed onto the back contact layer and the substrate to form a solar cell substructure, some areas within the substructure can trap residual atoms or compounds, such as sodium compounds Na₂Se and/or Na₂S. Such residual atoms or compounds on the substructure can have a negative impact on the overall performance of the solar cell. As such, in some embodiments, the solar cell substructure undergoes a washing or cleaning process prior to the buffer layer being formed onto the absorber layer. For the washing process, in some embodiments, the solar cell substructure can be placed within a washing chamber or tank. The tank includes a wash solution, such as deionized water, which can be used to remove the residual atoms or compounds from the solar cell substructure. However, when some of the residual atoms or compounds are being removed from the solar cell substructure, the free flowing components can alter the pH of the deionized water. Such an alteration of the pH can have an adverse impact on the washing process, such as preventing the removal of additional residual atoms or compounds from the solar cell substructure. Moreover, the overall solar cell substructure can be altered. For example, in some embodiments, the change in the pH of the wash solution can cause the absorber layer to become chemically altered.

The exemplary system, washing assembly, and method described herein enable a process for washing the solar cell substructure prior to the buffer layer being formed onto the absorber layer such that the pH of the wash solution is monitored and controlled during the wash process. For example, some embodiments provide a washing assembly for use with a solar cell fabrication system, wherein the washing assembly includes a wash chamber that includes a wash solution therein, and the wash chamber is configured to remove residual elements from at least one solar cell substructure using the wash solution. A control apparatus is coupled to the wash chamber, wherein the control apparatus facilitates the detection of the pH of the wash solution as the residual elements are being removed from the solar cell substructure. The control apparatus also facilitates a modification of the pH of the wash solution when the detected pH is different from a predefined threshold pH level or different from a predefined pH range.

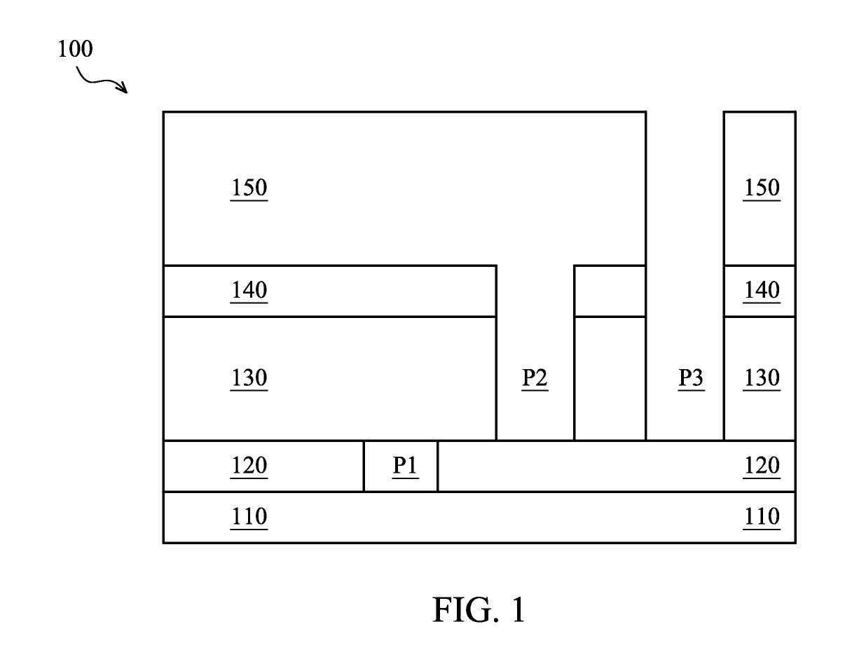

FIG. 1 illustrates a cross-section of a solar cell 100. Solar cell 100 includes a substrate 110, a back contact layer 120 formed onto substrate 110, an absorber layer 130 formed onto back contact layer 120, a buffer layer 140 formed onto absorber layer 130, and a front contact layer (also referred to as a transparent conductive oxide (TCO) layer) 150 above buffer layer 140.

Substrate 110 can include any suitable substrate material, such as glass. In some embodiments, substrate 110 can include a glass substrate, such as soda lime glass, or a flexible metal foil or polymer (e.g., a polyimide, polyethylene terephthalate (PET), polyethylene naphthalene (PEN)). Other embodiments include still other substrate materials.

Back contact layer 120 includes any suitable back contact material, such as metals. In some embodiments, back contact layer 120 can include molybdenum (Mo), platinum (Pt), gold (Au), silver (Ag), nickel (Ni), or copper (Cu). Other embodiments include still other back contact materials.

In some embodiments, absorber layer 130 includes any suitable absorber material, such as p-type semiconductors. In some embodiments, the absorber layer 130 can include a chalcopyrite-based material comprising, for example, Cu(In,Ga)Se2 (CIGS), cadmium telluride (CdTe), CulnSe2 (CIS), CuGaSe2 (CGS), Cu(In,Ga)Se2 (CIGS), Cu(In,Ga)(Se,S)2 (CIGSS), CdTe or amorphous silicon.

Buffer layer 140 includes any suitable buffer material, such as n-type semiconductors. In some embodiments, buffer layer 140 can include cadmium sulphide (CdS), zinc sulphide (ZnS), zinc selenide (ZnSe), indium(III) sulfide (In2S3), indium selenide (In2Se3), or Zn1-xMgxO, (e.g., ZnO). Other embodiments include still other buffer materials.

In some embodiments, front contact layer 150 includes an annealed TCO layer. The TCO material for the annealed TCO layer can include any suitable front contact material, such as metal oxides and metal oxide precursors. In some embodiments, the TCO material can include zinc oxide (ZnO), cadmium oxide (CdO), indium oxide (In2O3), tin dioxide (SnO2), tantalum pentoxide (Ta2O5), gallium indium oxide (GaInO3), (CdSb2O3), or indium oxide (ITO). The TCO material can also be doped with a suitable dopant. In some embodiments, ZnO can be doped with any of aluminum (Al), gallium (Ga), boron (B), indium (In), yttrium (Y), scandium (Sc), fluorine (F), vanadium (V), silicon (Si), germanium (Ge), titanium (Ti), zirconium (Zr), hafnium (Hf), magnesium (Mg), arsenic (As), or hydrogen (H). In other embodiments, SnO2 can be doped with antimony (Sb), F, As, niobium (Nb), or tantalum (Ta). In other embodiments, In2O3 can be doped with tin (Sn), Mo, Ta, tungsten (W), Zr, F, Ge, Nb, Hf, or Mg. In other embodiments, CdO can be doped with In or Sn. In other embodiments, GaInO3 can be doped with Sn or Ge. In other embodiments, CdSb2O3 can be doped with Y. In other embodiments, ITO can be doped with Sn. Other embodiments include still other TCO materials and corresponding dopants.

Solar cell 100 also includes interconnect structures that include three scribe lines, referred to as P1, P2, and P3. The P1 scribe line extends through the back contact layer 120 and is filled with the absorber layer material. The P2 scribe line extends through the buffer layer 140 and the absorber layer 130 and is filled with the front contact layer material. The P3 scribe line extends through the front contact layer 150, buffer layer 140 and absorber layer 130.

As will be explained in more detail with respect to the remaining figures, after absorber layer 130 is applied onto substrate 110 and back contact layer 120 to form a solar cell substructure, the substructure undergoes a washing process prior to buffer layer 140 being applied onto absorber layer 130 such that any residual atoms or compounds, such as sodium compounds Na₂Se and/or Na₂S, are removed from the solar cell substructure.

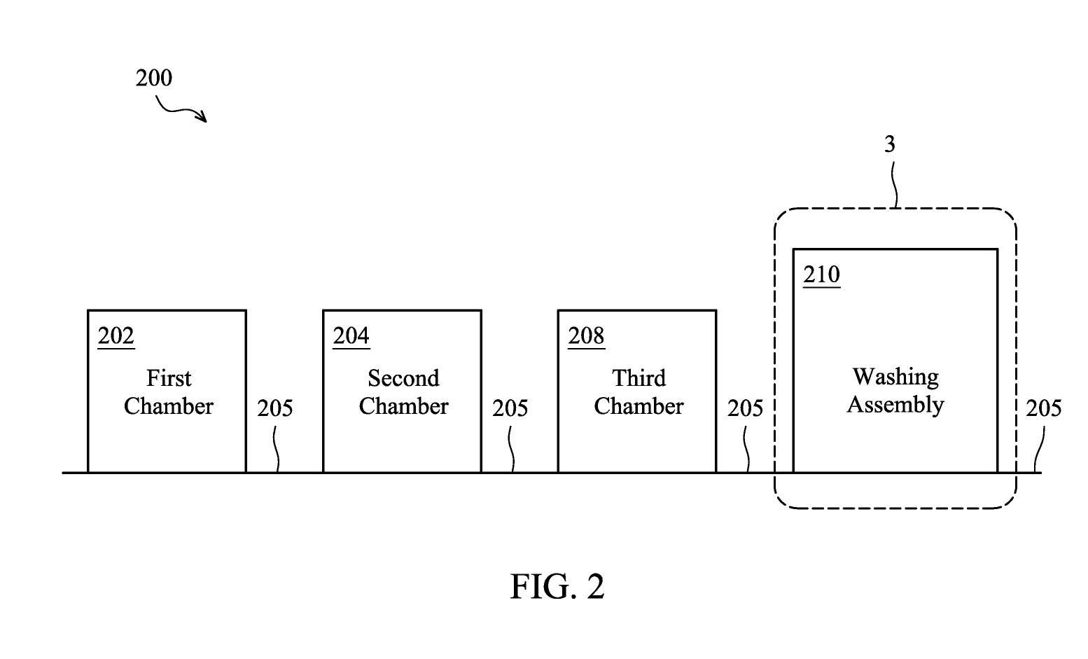

FIG. 2 is a block diagram of an exemplary solar cell fabrication system 200 that can be used for the fabrication of solar cell 100 (shown in FIG. 1). In some embodiments, system 200 includes at least one first chamber 202 that is configured to receive a substrate, such as substrate 110 (shown in FIG. 1) with back contact layer 120 (shown in FIG. 1) applied thereon, and to prepare substrate 110 with back contact layer 120 for further processing. For example, first chamber 202 can include a vacuum source (not shown), a heater (not shown), and/or a heat exchanger (not shown) to facilitate providing heat energy to substrate 110 with back contact layer, such that they are heated and ready to undergo further processing. The first chamber 202, in some embodiments, can include two or more chambers for performing different processes such as, but not limited to, sputtering, chemical vapor deposition (CVD) or atomic layer deposition (ALD).

A second chamber 204 is coupled to first chamber 202, via, for example, an endless conveyor 205, and second chamber 204 is configured to receive substrate 110 with back contact layer 120 from first chamber 202 via endless conveyor 205.

In some embodiments, second chamber 204 is configured to deposit a layer, such as absorber layer 130 (shown in FIG. 1) onto substrate 110 and back contact layer 120 to form solar cell 100 or a substructure of solar cell 100. As such, second chamber 204 can include, for example, chemical bath deposition (CBD) equipment (not shown), such as a heater (not shown). The CBD equipment can facilitate, for example, the formation of the metal chalcogenide thin films of absorber layer 130.

In some embodiments, system 200 also includes a third chamber 208 that is coupled to second chamber 204 via endless conveyor 205. In some embodiments, third chamber 208 is configured to conduct a post-processing of the formed substructure, such as completing the formation of the absorber layer 130. For example, third chamber 208 can also include inert gases, such as nitrogen gas, argon, and helium, as well as hydrogen selenide and hydrogen sulfide such that third chamber 208 can conduct a selenization process and a sulfurization process after the selenization process (SAS). In some embodiments, third chamber 208 may be a part of second chamber 204 to form a single chamber. For example, third chamber 208 can be within second 204 and has distinct walls. Alternatively, the functions of the second chamber 204 and third chamber 208 are both performed by a single chamber.

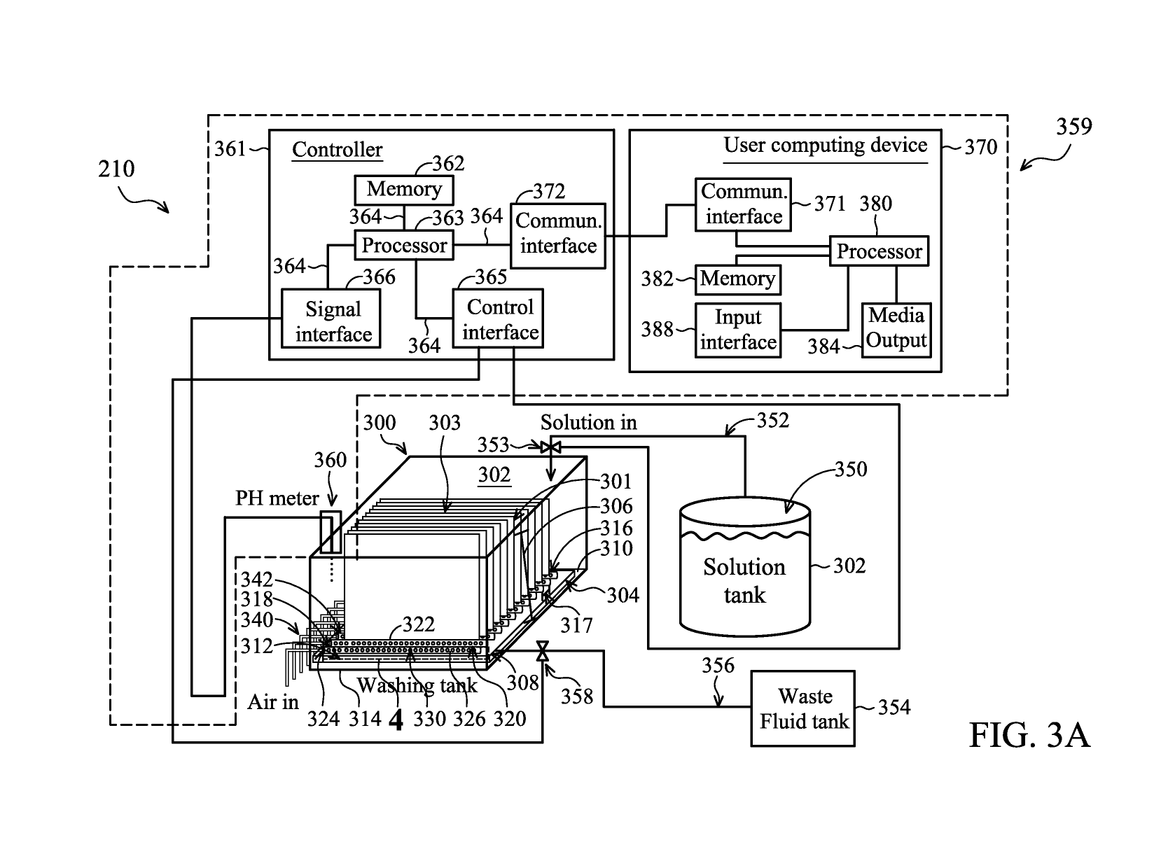

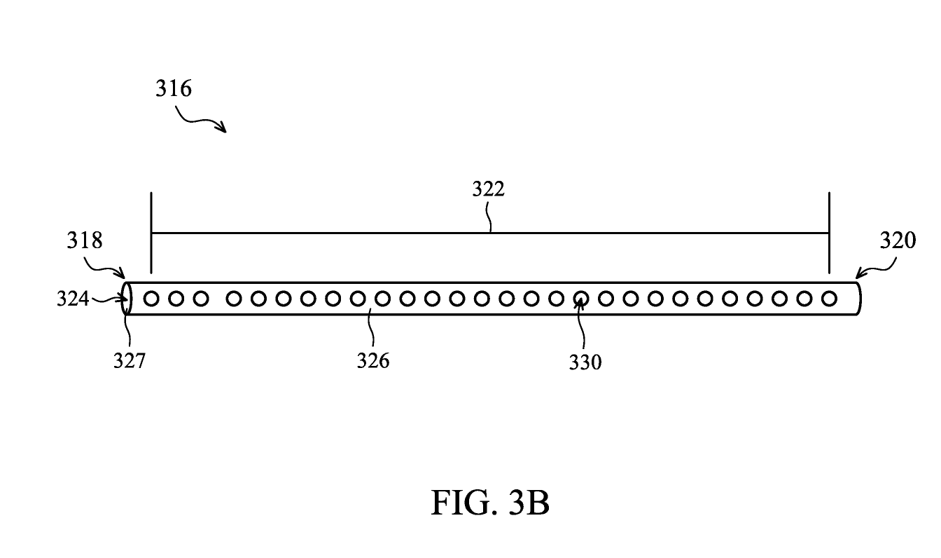

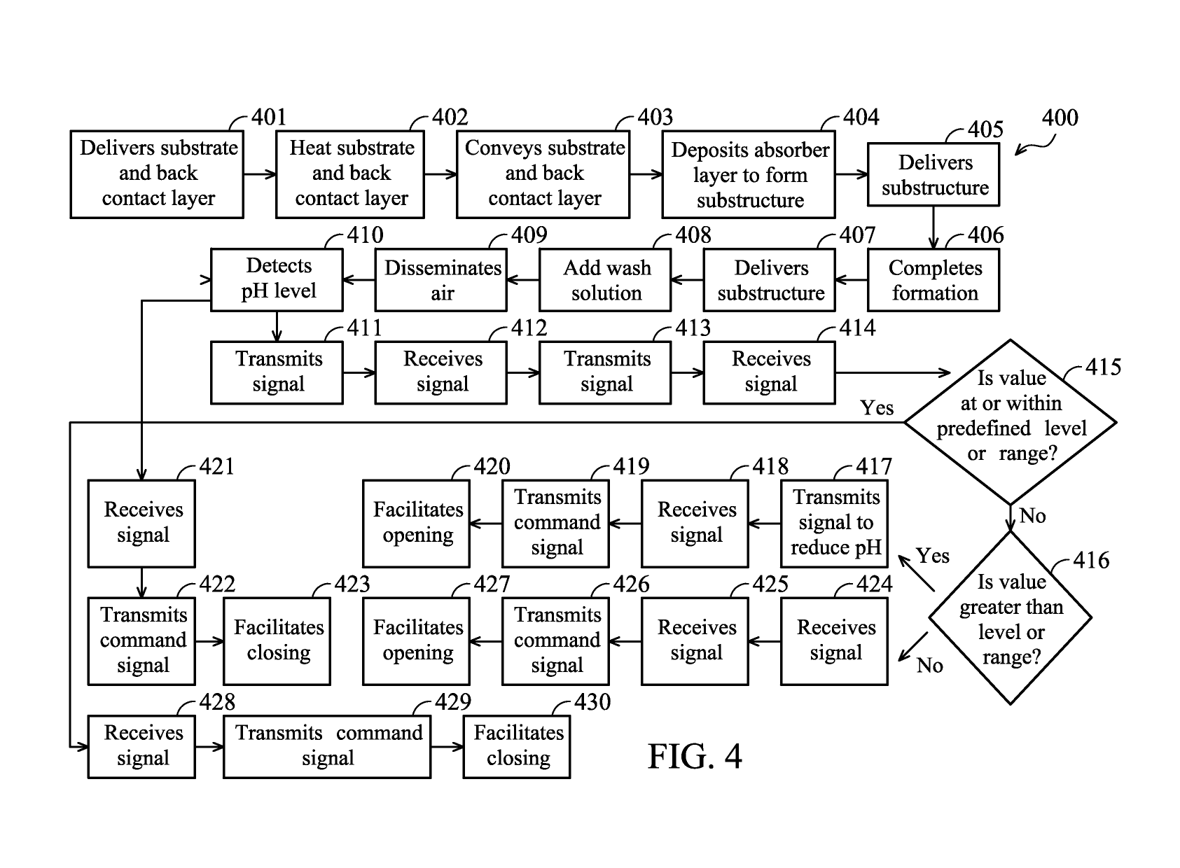

A washing assembly 210 can be coupled to third chamber 208 via endless conveyor 205 and washing assembly 210 can be positioned proximate to third chamber 208. As explained in detail with respect to FIGS. 3 and 4, washing assembly 210 is configured to perform a wash process for the solar cell substructure before buffer layer 140 (shown in FIG. 1) is applied onto absorber layer 130.

FIG. 3A illustrates washing assembly 210 that is coupled to third chamber 208 (shown in FIG. 2) and taken from area 3 (shown in FIG. 2). FIG. 3B illustrates a portion of washing assembly taken from area 4 (shown in FIG. 3A). Referring to FIG. 3A, washing assembly 210 includes a wash chamber 300 that is coupled to third chamber 208 via conveyor 205 (shown in FIG. 2). Wash chamber 300 is configured to receive and contain wash solution 302 therein. In some embodiments, wash chamber 300 is configured to receive at least one solar cell substructure, such as a solar cell substructure 303, which includes substrate 110 (shown in FIG. 1), back contact layer 120 (shown in FIG. 1), and absorber layer 130 (shown in FIG. 1) formed thereon, from third chamber 208. Wash chamber 300 is also configured to perform a wash process for substructure 303, such as, removing any residual elements, such as sodium compounds Na₂Se and/or Na₂S, that are formed on solar cell substructure 303. For example, in some embodiments, such residual elements are removed before buffer layer 140 is applied onto absorber layer 130.

In some embodiments, wash chamber 300 has a substantially rectangular shape with a first end portion 301 and a second end portion 304 a predefined distance 306 from first end portion 301. In some embodiments, a base platform 308 is sized and configured to be positioned on an interior surface 310 of second end portion 304 such that base platform 308 substantially covers interior surface 310. In some embodiments, base platform 308 includes a top surface 312 and an opposing bottom surface 314. Base platform 308 can be composed of any suitable material that is used for solar cell fabrication, such as a metal.

A plurality of conduits (e.g., pipes 316) are positioned on top surface 312 of base platform 308 such that each pipe 316 is positioned a predefined distance 317 from at least one other pipe 316. Referring to FIGS. 3A and 3B, each pipe 316 is substantially cylindrical with a first end portion 318 and a second end portion 320 positioned a predefined distance 322 from first end portion 318. An opening 324 extends from first end portion 318 to second end portion 320. Each pipe 316 has an exterior surface 326 and an opposing interior surface 327. Each pipe 316 also includes a plurality of apertures 330 on exterior surface 326. Each aperture 330 extends from exterior surface 326 through interior surface 327 of each pipe 316.

Referring to FIG. 3A, a plurality of air tubes 340 are positioned proximate to washing chamber 300 and each air tube 340 is coupled to chamber 300 via separate openings (not shown). The openings enable a portion of each air tube 340 to be positioned external to washing chamber 300 and another portion of each air tube 340 to be positioned inside washing chamber 300, such that each air tube 340 is coupled to a respectively different pipe 316. In some embodiments, an end portion 342 of each air tube 340 is coupled to first end portion 318 of each pipe 316. Accordingly, fluid, such as air, can be channeled from each air tube 340 to the respective pipe 316. For example, air can be channeled from end portion 342 of each air tube 340 to first end portion 318 of each pipe 316. Air can then be channeled through each pipe 316 and through second end portion 320 of each pipe 316. In some embodiments, as the air is being channeled from first end portion 318 of each pipe 316 to second end portion 320, air can also be channeled through apertures 330 such that air can be disseminated within wash solution 302. Each pipe 316 and air tube 340 can be fabricated from any suitable material used for solar cell fabrication, such as polymers and stainless steel. In some embodiments, each pipe 316 can be integrally formed with respective air tube 340. In other embodiments, air tubes 340 are separate conduits which terminate within pipes 316.

In some embodiments, a storage tank 350 is positioned proximate to wash chamber 300 and coupled to wash chamber 300 via a fluid conduit 352. In some embodiments, storage tank 350 includes wash solution 302 and delivers wash solution 302 to wash chamber 300 via conduit 352. A valve 353 is positioned within conduit 352. In some embodiments, wash solution 302 includes deionized water. A waste fluid tank 354 is also positioned proximate to wash chamber 300 and coupled to wash chamber 300 via a fluid conduit 356. In some embodiments, wash solution 302 can be delivered from wash chamber 300 to waste fluid tank 354 via conduit 356. A valve 358 is positioned in conduit 356.

In some embodiments, a control apparatus 359 is coupled to wash chamber 300. Control apparatus 359 includes a pH meter 360 that is positioned within wash chamber 300 such that pH meter 360 is positioned at least partially within wash solution 302. In some embodiments, pH meter 360 is configured to determine the pH level of wash solution 302 while solar cell substructure 303 is being washed therein. In some embodiments, the optimal pH range of wash solution 302 for washing solar cell substructure 303, such as removing the residual elements from solar cell substructure 303, is from 5.70 to 5.78. In some embodiments, an optimal pH value for washing solar cell substructure 303 is 5.74. In some embodiments, the temperature range for washing solar cell substructure 303 is from 25 degrees Celsius to 85 degrees Celsius and, in some embodiments, from 45 degrees Celsius to 75 degrees Celsius.

Control apparatus 359 also includes a controller 360 that is operatively coupled to vary the operation of washing assembly 210 as a function of values determined from pH meter 360 according to a programmed control algorithm. For example, in some embodiments, controller 360 is coupled to control at least one valve, such as valves 353 and 358. In some embodiments, controller 360 is enabled to facilitate operative features of valves 353 and 358, via features that include, without limitation, receiving inputs, transmitting outputs, and transmitting opening and closing commands.

In some embodiments, controller 361 can be a real-time controller and can include any suitable processor-based or microprocessor-based system, such as a computer system, that includes microcontrollers, reduced instruction set computer (RISC), an embedded microprocessor, application-specific integrated circuits (ASICs), logic circuits, and/or any other circuit or processor that is capable of executing the functions described herein. In one embodiment, controller 361 can be a microprocessor that includes read-only memory (ROM) and/or random access memory (RAM), such as, for example, a 32 bit microcomputer with 2 Mbit ROM and 64 Kbit RAM. As used herein, the term “real-time” refers to outcomes occurring within a short period of time after a change in the inputs affect the outcome, with the time period being a design parameter that can be selected based on the importance of the outcome and/or the capability of the system processing the inputs to generate the outcome.

In some embodiments, controller 361 includes a memory device 362 that stores executable instructions and/or one or more operating parameters representing and/or indicating an operating condition of washing assembly 210. Controller 361 also includes a processor 363 that is coupled to memory device 363 via a system bus 364. In some embodiments, processor 363 can include a processing unit, such as, without limitation, an integrated circuit (IC), an application specific integrated circuit (ASIC), a microcomputer, a programmable logic controller (PLC), and/or any other programmable circuit. Alternatively, processor 363 can include multiple processing units (e.g., in a multi-core configuration). The above examples are exemplary only, and thus are not intended to limit in any way the definition and/or meaning of the term “processor.”

In some embodiments, controller 361 includes a control interface 365 that is coupled to valve 353 and valve 358. Control interface 365 is also configured to control an operation of valves 353 and 358. For example, processor 363 can be programmed to generate one or more control parameters that are transmitted to control interface 365. Control interface 365 can then transmit a control signal to modulate, open, or close valves 353 and 358, for example.

Various connection protocols can be used for communications between control interface 365 and valves 353 and 358. Such connection protocols can include, without limitation, an electrical conductor, a low-level serial data connection, such as Recommended Standard (RS) 232 or RS-485, a high-level serial data connection, such as USB, a field bus, a “PROFIBUS®,” or Institute of Electrical and Electronics Engineers (IEEE) 1394 (a/k/a FIREWIRE), a parallel data connection, such as IEEE 1284 or IEEE 488, a short-range wireless communication channel (personal area network) such as “BLUETOOTH,” and/or a private (e.g., inaccessible outside system) network connection, whether wired or wireless. “PROFIBUS” is a registered trademark of Profibus Trade Organization of Scottsdale, Ariz. IEEE is a registered trademark of the Institute of Electrical and Electronics Engineers, Inc., of New York, N.Y. “BLUETOOTH” is a registered trademark of Bluetooth SIG, Inc. of Kirkland, Wash.

In some embodiments, controller 361 includes a signal interface 366 that is communicatively coupled to pH meter 360. As such, pH meter 360 can transmit signals representative of the detected pH values to controller 361. The signals can be transmitted continuously in some embodiments. In other embodiments, the signals can be transmitted periodically or only once, for example. In some embodiments, different bases are used for signal timings. Furthermore, the signals can be transmitted in either an analog form or in a digital form. Various connections are available between signal interface 366 and pH meter 360. Such connections can include, without limitation, an electrical conductor, a low-level serial data connection, such as RS 232 or RS-485, a high-level serial data connection, such as USB or IEEE® 1394, a parallel data connection, such as IEEE® 1284 or IEEE® 488, a short-range wireless communication channel such as BLUETOOTH®, and/or a private (e.g., inaccessible outside system) network connection, whether wired or wireless.

Control apparatus 359 can also include a user computing device 370 that is coupled to controller 361 via, for example, a network (not shown). Computing device 370 includes a communication interface 371 that is coupled to a communication interface 372 contained within controller 361. User computing device 370 includes a processor 380 for executing instructions. In some embodiments, executable instructions are stored in a memory device 382. Processor 380 can include one or more processing units (e.g., in a multi-core configuration). Memory device 382 is any device allowing information, such as executable instructions and/or other data, to be stored and retrieved. User computing device 370 also includes at least one media output component 384 for use in presenting information to a user. Media output component 384 is any component capable of conveying information to the user. Media output component 384 can include, without limitation, a display device (not shown) (e.g., a liquid crystal display (LCD), an organic light emitting diode (OLED) display, or an audio output device (e.g., a speaker or headphones)).

In some embodiments, user computing device 370 includes an input interface 388 for receiving input from a user. Input interface 388 can include, for example, a keyboard, a pointing device, a mouse, a stylus, a touch sensitive panel (e.g., a touch pad or a touch screen), a gyroscope, an accelerometer, a position detector, and/or an audio input device. A single component, such as a touch screen, can function as both an output device of media output component 384 and input interface 388.

Prior to the operation of solar cell fabrication system 200 (shown in FIG. 2) and/or operation of washing assembly 210, a user can input predefined threshold level(s) or ranges to computing device 370. For example, the user can input the predefined target threshold level of 5.74 for the pH of wash solution 302. In some embodiments, the user can input the predefined target range of 5.70 to 5.78 for the pH of wash solution 302.

During operation, substrate 110 with back contact layer 120 formed thereon is delivered from first chamber 202 (shown in FIG. 2), via endless conveyor 205, wherein substrate 110 with back contact layer 120 can be heated in preparation for further processing. Substrate 110 with back contact layer 120 are then delivered to second chamber 204 (shown in FIG. 2) from first chamber 202 such that one or more layer(s), such as absorber layer 130, can be deposited onto substrate 110 to form solar cell substructure 303 via processes, such as the CBD process. Solar cell substructure 303 can then be delivered, via endless conveyor 205, to third chamber 208 to complete the formation of absorber layer 130. Solar cell substructure 303 can then be delivered from third chamber 208 to wash chamber 300 via endless conveyor 205. In wash chamber 300, solar cell substructure 303 can undergo a wash process. For example, residual compounds or elements, such as sodium compounds Na₂Se and/or Na₂S, can be removed from a surface substructure 303 by using wash solution 302 within wash chamber 300 prior to buffer layer 140 being applied onto absorber layer 130.

As explained in more detail below with respect to FIG. 4, during the wash process, wash solution 302 within wash chamber 300 is monitored and controlled with control apparatus 359 to ensure that the pH for wash solution 302 is at or within the aforementioned predefined threshold pH level or range. For example, in some embodiments, pH meter 360 detects the pH level for wash solution 302. As explained in more detail below with respect to FIG. 4, after the pH level of wash solution 302 is detected, a signal representative of the detected value is transmitted from pH meter 360 to controller 361. Controller 361 transmits the signal to computing device 370 such that computing device 370 determines whether the detected value is at or within the respective above-referenced predefined threshold level or range. If the detected value is greater than or less than the respective predefined threshold level or range, then computing device 370 transmits a signal to controller 361 to modify the pH level of wash solution 302. As explained in more detail below with respect to FIG. 4, in some embodiments, controller 361 can transmit control parameters to facilitate removing or adding wash solution 302 from wash chamber 300 to adjust the pH level of wash solution 302. As such, washing assembly 210 enables a process for washing solar cell substructure 303 such that the pH of wash solution 302 is maintained at target levels during the wash process.

FIG. 4 is a flow diagram 400 of an exemplary method for monitoring the process for the fabrication of solar cell 100 (shown in FIG. 1) by using washing assembly 210 (shown in FIGS. 2, 3A, and 3B). In step 401, substrate 110 (shown in FIG. 1) with back contact layer 120 (shown in FIG. 1) is delivered to first chamber 202 (shown in FIG. 2), via endless conveyor 205 (shown in FIG. 2), wherein substrate 110 and back contact layer 120 are heated in preparation for further processing in step 402.

In step 403, substrate 110 and back contact layer 120 are conveyed on endless conveyor 205 from first chamber 202 to second chamber 204 (shown in FIGS. 2 and 3A). In step 404, absorber layer 130 (shown in FIG. 1) or a precursor layer is deposited onto substrate 110 and back contact layer 120 to form solar cell substructure 303 (shown in FIG. 3A) via processes, such as a CBD process. In step 405, substructure 303 is delivered to third chamber 208 (shown in FIG. 2) to complete the formation of absorber layer 130 onto substrate 110 and back contact layer 120 in step 406 via, for example, SAS. In step 407, substructure 303 is delivered to wash chamber 300 (shown in FIG. 3A), wherein the substructure undergoes a wash process. For example, in step 408, wash solution 302 is added from storage tank 350 (shown in FIG. 3A) to chamber 300. In some embodiments, a user can input a command for the addition of wash solution 302 with computing device 370 (shown in FIG. 3A) and computing device 370 can transmit the command to controller 361 (shown in FIG. 3A) via a signal. The controller 361 can then transmit a command signal to valve 353 (shown in FIG. 3A), wherein the command signal facilitates the opening of valve 353 such that wash solution 302 from storage tank 350 can be channeled to wash chamber 300 such that substructure 303 is at least partially immersed within wash solution 302. In some embodiments, wash solution 302 can already be contained within wash chamber 300 when substructure 303 is delivered to wash chamber 303. Residual compounds and elements, such as sodium compounds Na₂Se and/or Na₂S, are then removed from the surface of substructure 303 using wash solution 302, wherein wash solution 302 initially has the optimal pH of 5.74.

During the wash process, in step 409, air is disseminated within wash solution 302 in some embodiments. For example, fluid, such as air, can be channeled from each air tube 340 (shown in FIG. 3A) to the respective pipe 316 (shown in FIGS. 3A and 3B). For example, air can be channeled from end portion 342 (shown in FIG. 3A) of each air tube 340 to first end portion 318 (shown in FIGS. 3A and 3B) of each pipe 316. The air can then be channeled through each pipe 316 and through second end portion 320 (shown in FIGS. 3A and 3B) of pipe 316. In some embodiments, as the air is being channeled from first end portion 318 of each pipe 316 to second end portion 320, air can also be channeled through apertures 330 (shown in FIGS. 3A and 3B) such that air can be disseminated within wash solution 302.

During the wash process, wash solution 302 within wash chamber 300 is monitored and controlled with control apparatus 359 to ensure that the pH for wash solution 302 is at or within the aforementioned predefined threshold pH level or range. For example, in some embodiments, absorber layer 130 includes residual compounds, such as sodium compounds Na₂Se and/or Na₂S. The sodium can be removed from absorber layer 130 by the deionized water in wash solution 302. For example, when deionized water is added to Na₂S, the following Equation 1 occurs.

Na₂S+H₂O→2Na++HS−+OH− Equation 1

As shown in Equation 1, the wash process results in the production of hydroxide ions that can raise the pH of the deionized water in wash solution 302. In some embodiments, the optimal pH of 5.74 of wash solution 302 can be raised to 5.99 or 6.08. As such, washing assembly 210 monitors the pH level of wash solution 302 and modifies the pH when the pH level changes from the target level or range. For example, during the wash process, in step 410, pH meter 360 (shown in FIG. 3A) detects the pH level for wash solution. In some embodiments, pH meter 360 detects the pH value of wash solution 302 continuously during the wash process. In other embodiments, pH meter 360 detects the pH value of wash solution 302 periodically during the wash process at various times that are programmed by a user via computing device 370. In other embodiments, pH meter 360 can detect the pH value once during the wash process.

In step 411, pH meter 360 transmits a signal representative of the detected pH value(s) of wash solution 302 to controller 361. In some embodiments, pH meter 360 transmits the signals after each pH value is detected. For example, if pH meter 360 is detecting concentration values continuously during the wash process, then pH meter 360 will transmit signals of the detected pH values continuously to controller 361 during the wash process.

Controller 361 receives the signal of the detected the detected pH value(s) in step 412 via signal interface 366 (shown in FIG. 3A). In step 413, controller 361 transmits the signal to computing device 370 and, in step 414, computing device 370 receives the signal. In step 415, computing device 370 determines whether the detected value is at or within the above-referenced predefined threshold level or range for the pH level for wash solution 302. If the value at the predefined threshold hold level or within the predefined threshold range, then the wash process continues with no further modifications to wash solution 302 and steps 410 to 415 are repeated to continue the detection process.

If the detected pH value is not within or at the predefined threshold range or level, then, in step 416, computing device 370 determines whether the detected value is either greater than or less than the predefined threshold range or level. If the detected value is greater than the predefined threshold level or range, then computing device 370 transmits a signal to controller 361 to reduce the pH level of wash solution 302 in step 417. In some embodiments, two thresholds are used, defining a target range. If the pH is greater than the maximum value of the range, the computing device 370 transmits a signal to controller 361 to reduce the pH level. If the pH is less than the minimum value of the range, the computing device 370 transmits a signal to controller 361 to increase the pH level. If the pH is between the minimum and maximum, no change in pH is initiated.

Controller 361 receives the signal in step 418. In step 419, controller 361 transmits a command signal to valve 353, wherein the command signal facilitates the opening of valve 353 in step 420 such that wash solution 302 from storage tank 350 can be channeled to wash chamber 300. The addition of wash solution 302 from storage tank enables the pH of wash solution in wash chamber 300 to decrease until the target pH level or range is reached for wash solution 302 and steps 410 to 415 are repeated. For example, when the detected value of wash solution 302 is identified as being at or within the predefined threshold level or range during the continuous detection of the values and transmission of signals of the detected values as steps 410 to 415 above are repeated, then controller 361 transmits a different command signal valve 353. For example, controller 361 receives a signal, in step 421, from computing device 370, wherein the signal indicates that the pH value is now at or within the predefined threshold level or range. In step 422, controller 361 transmits a command signal to valve 353, wherein the command signal facilitates the closing of valve 353 in step 423 such that wash solution 302 is no longer being added to wash chamber 300 from storage tank 350.

If, in step 415, computing device 370 determines that the detected value is less than the predefined threshold level or range, then computing device 370 transmits a signal to controller 361 to increase the pH level of wash solution 302 in step 424. Controller 361 receives the signal in step 425. In step 426, controller 361 transmits a command signal to valve 358 (shown in FIG. 3A), wherein the command signal facilitates the opening of valve 358 in step 427 such that wash solution 302 can be channeled from chamber 300 to waste fluid tank 354 (shown in FIG. 3A). The removal of wash solution 302 from chamber 300 enables the pH of wash solution to increase until the optimal pH level or range is reached for wash solution 302 and steps 410 to 415 are repeated. For example, when the detected pH value of wash solution 302 is identified as being at or within the predefined threshold level or range during the continuous detection of the values and transmission of signals of the detected values as steps 410 to 415 above are repeated, then controller 361 transmits a different command signal valve 353. For example, controller 361 receives a signal, in step 428, from computing device 370, wherein the signal indicates that the pH value is now at or within the predefined threshold level or range. In step 429, controller 361 transmits a command signal to valve 358, wherein the command signal facilitates the closing of valve 358 in step 430 such that wash solution 302 is no longer being removed from wash chamber 300. In some embodiments, steps 410-430 are repeated continuously through the duration of the wash process to ensure that the pH level of wash solution 302 is maintained at an optimal level or within an optimal range during the wash process. After the wash process is complete and the residual elements have been removed, solar cell substructure 303 can be transferred to another chamber (not shown) such that buffer layer 140 can be formed onto absorber layer 130.

Some embodiments described herein enable a process for washing a solar cell substructure prior to the buffer layer being formed onto the absorber layer such that the pH of the wash solution is monitored and controlled during the wash process. For example, some embodiments provide a washing assembly for use with a solar cell fabrication system, wherein the washing assembly includes a wash chamber that includes a wash solution therein and the wash chamber is configured to remove residual elements from at least one solar cell substructure using the wash solution. A control apparatus is coupled to the wash chamber, wherein the control apparatus facilitates the detection of the pH of the wash solution as the residual elements are being removed from the solar cell substructure. The control apparatus also facilitates a modification of the pH of the wash solution when the detected pH is different from a predefined threshold pH level or different from a predefined pH range.

In some embodiments, a method for monitoring the process of fabricating solar cells is provided. The method includes delivering at least one solar cell substructure to a wash chamber having a wash solution therein, such that the solar cell substructure is at least partially immersed within the wash solution. A residual material is removed from the solar cell substructure using the wash solution. A pH value of the wash solution is detected automatically while the solar cell substructure is at least partially immersed within the wash solution, via a control apparatus. The method also includes determining whether the detected pH value is at a predefined threshold pH level or within a predefined pH range for the wash solution, via the control apparatus. The pH value of the wash solution is modified automatically if the detected pH value is different from the predefined threshold pH level or different from the predefined pH range.

In some embodiments, a washing assembly is provided and includes a wash chamber adapted to contain a wash solution therein, wherein the wash chamber is configured to receive and contain at least one solar cell substructure therein, such that the solar substructure is at least partially immersed within the wash solution, for removing a residual material from the solar cell substructure. A control apparatus is coupled to the wash chamber. The control apparatus includes a pH meter positioned at least partially within the wash chamber for positioning within the wash solution, wherein the pH meter is configured to detect a pH value of the wash solution while the solar cell substructure is at least partially immersed within the wash solution. A controller is coupled to the pH meter, wherein the controller is configured to determine whether the detected pH value is at a predefined threshold pH level or within a predefined pH range for the wash solution and to initiate modification of the pH value of the wash solution if the detected pH value is different from the predefined threshold pH level or different from the predefined pH range.

In some embodiments, a solar cell fabrication system is provided. The solar cell fabrication system includes a deposition chamber that is configured to receive at least one solar cell substructure and to perform a reaction process on the solar cell substructure. A washing assembly is coupled to the deposition chamber. The washing assembly includes a wash chamber that is adapted to contain a wash solution therein, wherein the wash chamber is configured to receive and contain the solar cell substructure therein, such that the solar substructure is at least partially immersed within the wash solution, for removing a residual material from the solar cell substructure. A control apparatus is coupled to the wash chamber. The control apparatus includes a pH meter positioned at least partially within the wash chamber for positioning within the wash solution, wherein the pH meter is configured to detect a pH value of the wash solution while the solar cell substructure is at least partially immersed within the wash solution. A controller is coupled to the pH meter, wherein the controller is configured to determine whether the detected pH value is at a predefined threshold pH level or within a predefined pH range for the wash solution and to initiate modification of the pH value of the wash solution if the detected pH value is different from the predefined threshold pH level or different from the predefined pH range.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
delivering at least one solar cell substructure to a wash chamber having a wash solution therein, such that the at least one solar cell substructure is at least partially immersed within the wash solution;
removing a residual material from the at least one solar cell substructure using the wash solution;
detecting a pH value of the wash solution automatically while the at least one solar cell substructure is at least partially immersed within the wash solution, via a control apparatus;
determining whether the detected pH value is at a predefined threshold pH level or within a predefined pH range for the wash solution, via the control apparatus; and
modifying the pH value of the wash solution automatically if the detected pH value is different from the predefined threshold pH level or different from the predefined pH range.

2. The method of claim 1, further comprising positioning a plurality of pipes spaced apart from each other at an end portion of the wash chamber, wherein each of the plurality of pipes includes a plurality of apertures.

3. The method of claim 2, further comprising channeling a fluid through each of the plurality of pipes such that the fluid is channeled through the plurality of apertures.

4. The method of claim 3, wherein channeling a fluid comprises channeling an air flow through each of the plurality of pipes.

5. The method of claim 1, wherein adding a wash solution comprises adding deionized water into the wash chamber.

6. The method of claim 1, wherein modifying the pH value of the wash solution comprises removing at least a portion of the wash solution from the wash chamber.

7. The method of claim 1, wherein modifying the pH value of the wash solution comprises adding additional wash solution from a storage tank to the wash chamber.

8. A washing assembly comprising:
a wash chamber adapted to contain a wash solution therein, said wash chamber configured to receive and contain at least one solar cell substructure therein, such that the at least one solar substructure is at least partially immersed within the wash solution, for removing a residual material from the at least one solar cell substructure; and
a control apparatus coupled to said wash chamber, said control apparatus comprising:
a pH meter positioned at least partially within said wash chamber for positioning within the wash solution, said pH meter configured to detect a pH value of the wash solution while the at least one solar cell substructure is at least partially immersed within the wash solution; and
a controller coupled to said pH meter, said controller configured to determine whether the detected pH value is at a predefined threshold pH level or within a predefined pH range for the wash solution and to initiate modification of the pH value of the wash solution if the detected pH value is different from the predefined threshold pH level or different from the predefined pH range.

9. The washing assembly of claim 8, wherein said wash chamber comprises a plurality of pipes that are spaced apart from each other at an end portion of said wash chamber, wherein each of said plurality of pipes comprises a plurality of apertures.

10. The washing assembly of claim 9, wherein said wash chamber is further configured to channel a fluid through each of said plurality of pipes such that the fluid is channeled through said plurality of apertures.

11. The washing assembly of claim 10, wherein the fluid is air.

12. The washing assembly of claim 8, further comprising a storage tank positioned proximate to said wash chamber, said storage tank is configured to channel the wash solution to said wash chamber.

13. The washing assembly of claim 12, wherein said controller is configured to initiate the addition of at least a portion of the wash solution in said storage tank to said wash chamber.

14. The washing assembly of claim 8, wherein the wash solution includes deionized water.

15. The washing assembly of claim 8, wherein said controller is configured to initiate the removal of at least a portion of the wash solution from said wash chamber.

16. A solar cell fabrication system comprising:
a deposition chamber configured to receive at least one solar cell substructure and to perform a reaction process on the at least one solar cell substructure; and
a washing assembly coupled to said deposition chamber, said washing assembly comprises:
a wash chamber adapted to contain a wash solution therein, said wash chamber configured to receive and contain the at least one solar cell substructure therein, such that the at least one solar substructure is at least partially immersed within the wash solution, for removing a residual material from the at least one solar cell substructure; and
a control apparatus coupled to said wash chamber, said control apparatus comprising:
a pH meter positioned at least partially within said wash chamber for positioning within the wash solution, said pH meter configured to detect a pH value of the wash solution while the at least one solar cell substructure is at least partially immersed within the wash solution; and
a controller coupled to said pH meter, said controller configured to determine whether the detected pH value is at a predefined threshold pH level or within a predefined pH range for the wash solution and to initiate modification of the pH value of the wash solution if the detected pH value is different from the predefined threshold pH level or different from the predefined pH range.

17. The solar cell fabrication system of claim 16, wherein said wash chamber comprises a plurality of pipes that are spaced apart from each other at an end portion of said wash chamber, wherein each of said plurality of pipes comprises a plurality of apertures.

18. The solar cell fabrication system of claim 17, wherein said wash chamber is further configured to channel a fluid through each of said plurality of pipes such that the fluid is channeled through said plurality of apertures.

19. The solar cell fabrication system of claim 16, wherein said controller is configured to initiate the removal of at least a portion of the wash solution from said wash chamber.

20. The solar cell fabrication system of claim 16, wherein said controller is configured to initiate the addition of at least a portion of the wash solution from a storage tank to said wash chamber.
